(19) United States
(12) Patent Application Publication
(10) Pub. No.: US 2024/0321619 A1
(43) Pub. Date: Sep. 26, 2024

(54) SUBSTRATE SUPPORTER

(71) Applicant: SAMSUNG ELECTRONICS CO., LTD., Suwon-si (KR)

(72) Inventors: Yunjae Lee, Suwon-si (KR); Jun Hyung Kim, Suwon-si (KR); Sangyeon Oh, Suwon-si (KR); Jihyeong Lee, Suwon-si (KR); Yonjoo Kang, Suwon-si (KR); Youngil Kang, Suwon-si (KR); Minsung Kim, Suwon-si (KR); Inhwan Park, Suwon-si (KR)

(21) Appl. No.: 18/439,492

(22) Filed: Feb. 12, 2024

(30) Foreign Application Priority Data
Mar. 23, 2023 (KR) 10-2023-0038062
Aug. 9, 2023 (KR) 10-2023-0104316

(51) Int. Cl. H01L 21/683; H01L 21/02; H01L 21/67

(52) U.S. Cl. CPC H01L 21/6833; H01L 21/67288; H01L 21/02271

(57) ABSTRACT

The present disclosure relates to substrate supporters and substrate processing apparatuses. An example substrate supporter includes an upper surface on which a substrate is loaded, a base, an outer dam extending along an edge of the base, a contact band connected with the outer dam, extending along the circumferential direction of the base, and onto which the substrate is loaded, and a first contact pattern disposed adjacent to the contact band and extending into an inside of the contact band, the first contact pattern extending along the circumferential direction of the base, where an area of the first contact pattern is larger than an area where the contact band overlaps with the substrate.

### CROSS-REFERENCE TO RELATED APPLICATIONS

This application claims priority to and the benefit of Korean Patent Application No. 10-2023-0038062 filed in the Korean Intellectual Property Office on Mar. 23, 2023, and Korean Patent Application No. 10-2023-0104316 filed in the Korean Intellectual Property Office on Aug. 9, 2023, the entire contents of which are incorporated herein by reference.

### BACKGROUND

A manufacturing technology of semiconductor devices includes a deposition process and an etching process to form a processing film on a wafer. The deposition process may include a physical deposition process and a chemical deposition process. The deposition apparatus and the etching apparatus used in the deposition process include a wafer chuck that maintains the wafer in a stable state in order to deposit a uniform processing film on the wafer or uniformly etch the material on the wafer. The wafer chuck is needed to hold the wafer in place to prevent it from moving or misaligning during the deposition process or the etching process.

There are various types of the wafer chucks, including a mechanical chuck that directly grabs the wafer using a mechanical clamp on the external circumferential surface of the wafer, a vacuum chuck that grabs the wafer with vacuum from the back of the wafer, and an electrostatic chuck that catches the wafer with an electrostatic attraction force.

### SUMMARY

The present disclosure relates to substrate supporters, including a substrate supporter with improved reliability, and substrate processing apparatuses including the same.

In some implementations, a substrate supporter includes an upper surface on which a substrate is loaded includes a base; an outer dam extending along the edge of the base; a contact band connected to the outer dam, extending along the circumferential direction of the base, and onto which the substrate is loaded; and a first contact pattern disposed closest to the contact band into the inside of the contact band and extending along the circumferential direction of the base, wherein the area of the first contact pattern is larger than the area where the contact band overlaps with the substrate.

In some implementations, a substrate supporter including an upper surface on which a substrate is loaded, comprising a base including an inner region and an outer region surrounding the inner region; an outer dam extending along the edge of the base; an inner contact pattern arranged with the same interval in the inner region; a contact band connected to the outer dam and extending along the circumferential direction of the base in the outer region, and onto which the substrate is loaded; and a first contact pattern disposed closest to the contact band into the inside of the contact band and extending along the circumferential direction of the base in the outer region, and the area of the first contact pattern is larger than the area where the contact band overlaps with the substrate.

In some implementations, a substrate supporter includes an upper surface on which a substrate is loaded, includes a base; an outer dam extending along the edge of the base; a contact band connected to the outer dam, extending along the circumferential direction of the base, and onto which the substrate is loaded; a first contact pattern disposed adjacent to the inside of the contact band and extending along the circumferential direction of the base; and a second contact pattern disposed adjacent to the inside of the first contact pattern and extending along the circumferential direction of the base, wherein the first contact pattern is disposed between the outer dam and the second contact pattern, and a ratio of an area where the first contact pattern is in contact with the substrate to the entire area of the substrate is greater than a ratio of an area where the contact band is in contact with the substrate to the entire area of the substrate.

In some implementations, according to the substrate supporter and the substrate processing apparatus including the same, as the contact ratio C/R of the first contact pattern is larger than the contact ratio C/R of the contact band, even when the substrate with a warpage is loaded, the contact band and the first contact pattern may chuck the substrate with a uniform electrostatic force. Accordingly, it is possible to prevent a damage to the bottom surface of the substrate due to an excessive electrostatic force acting on the edge of the substrate, and the reliability of the substrate processing apparatus may be improved.

### BRIEF DESCRIPTION OF THE DRAWINGS

FIG. 1 is a cross-sectional view showing an example of a substrate processing apparatus.

FIG. 2 is a cross-sectional view showing an example of a substrate supporter of a substrate processing apparatus.

FIG. 3 is a top plan view showing an example of a substrate supporter of a substrate processing apparatus.

FIG. 4 is an example enlarged top plan view of a region of FIG. 3.

FIG. 5 is an enlarged cross-sectional view of a part of an example of a substrate supporter.

FIG. 6 to FIG. 10 are example top plan views corresponding to a region of FIG. 3.

FIG. 11 to FIG. 13 are top plan views showing an example of a constant voltage electrode of a substrate processing apparatus.

### DETAILED DESCRIPTION

The present disclosure will be described more fully hereinafter with reference to the accompanying drawings, in which implementations of the disclosure are shown. As those skilled in the art would realize, the described implementations may be modified in various different ways, all without departing from the spirit or scope of the present disclosure.

In order to clarify the present disclosure, parts that are not connected with the description will be omitted, and the same elements or equivalents are referred to by the same reference numerals throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

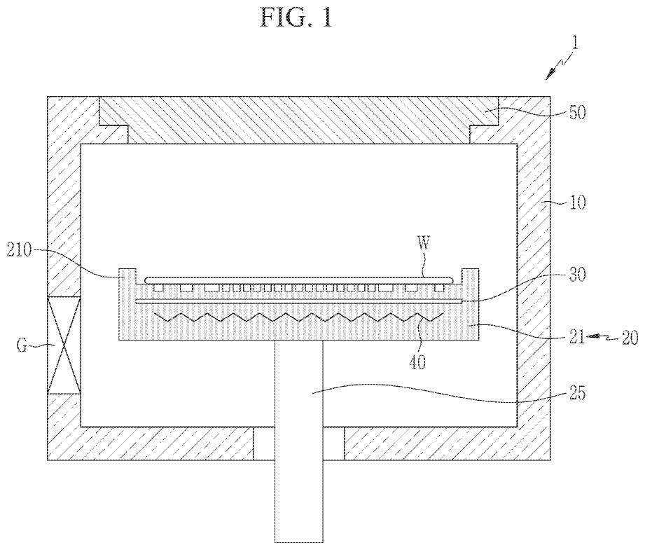

A substrate processing apparatus 1 according to an implementation is described with reference to FIG. 1 to FIG. 3.

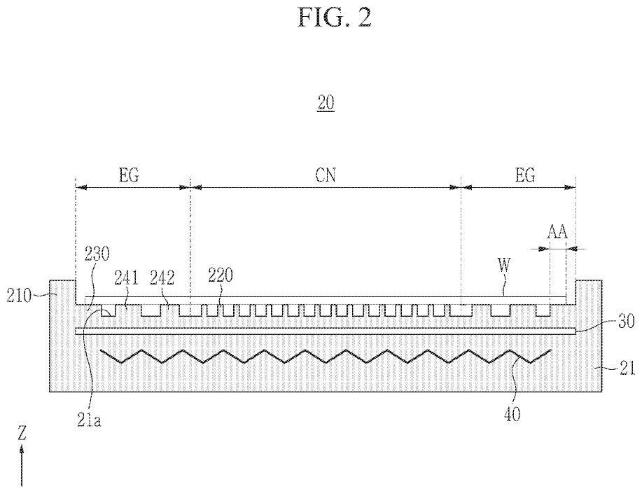

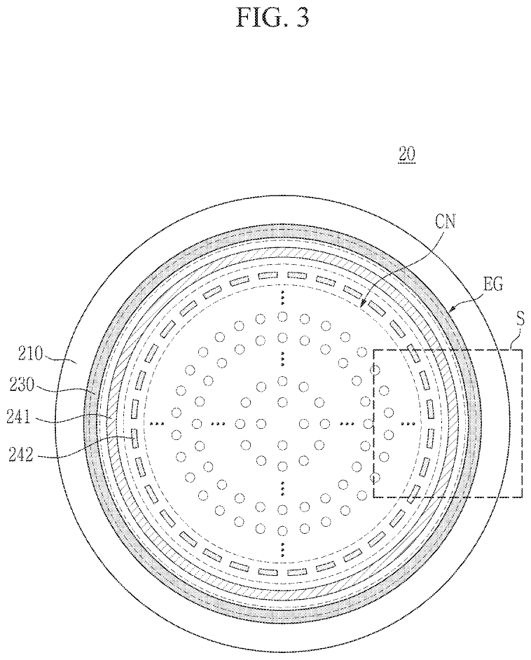

FIG. 1 is a cross-sectional view showing an example of a substrate processing apparatus. FIG. 2 is a cross-sectional view showing an example of a substrate supporter of a substrate processing apparatus. FIG. 3 is a top plan view showing an example of a substrate supporter of a substrate processing apparatus.

Referring to FIG. 1 to FIG. 3, a substrate processing apparatus 1 according to an implementation may be an apparatus that performs a process for processing a substrate W for manufacturing a semiconductor device. In some implementations, the substrate processing apparatus 1 may be an etching device or a deposit device. For example, the substrate processing apparatus 1 may perform a chemical vapor deposition (CVD) or a plasma enhanced chemical deposition (PECVD) process on the substrate W. Alternatively, the substrate processing apparatus 1 may perform a plasma etch process on the substrate W, but is not limited thereto.

The substrate processing apparatus 1 according to an implementation may include a chamber 10, a substrate supporter 20, and a showerhead structure 50.

The chamber 10 may provide an internal space to process the substrate W. The substrate supporter 20 may be disposed within the internal space of chamber 10. In the internal space of chamber 10, the processes such as depositing a thin film or etching a thin film on the substrate W supported by the substrate supporter 20 may be performed. The chamber 10 may include metallic materials such as aluminum (Al), but is not limited thereto. Additionally, on one side of the chamber 10, a gate G that may load or unload the substrate W into the internal space may be disposed.

The substrate W may be provided within the internal space of the chamber 10. For example, the substrate W may be loaded on the substrate supporter 20, and an etching process or a deposition process may be performed on the surface of the substrate W. The substrate W may be, for example, a semiconductor substrate containing silicon or germanium. However, it is not limited to this, and the substrate W may be a SOI (silicon on insulator) substrate.

The substrate supporter 20 may be provided within the chamber 10. The substrate supporter 20 may be disposed in the lower part of the chamber 10. For example, the substrate supporter 20 may be disposed on a vertical supporter 25 that extends passing through the chamber 10 within the chamber 10. That is, the substrate supporter 20 may be fixed by the vertical supporter 25. The substrate supporter 20 may include a dielectric material. For example, the substrate supporter 20 may include aluminum nitride (AlN).

In some implementations, the substrate W may be loaded on the upper surface of the substrate supporter 20. The substrate W may be chucked on the substrate supporter 20. For example, due to the electrostatic force acting between the substrate supporter 20 and the substrate W, the substrate W may be chucked on the substrate supporter 20.

The substrate supporter 20 according to an implementation may include a base 21, an outer dam 210, an inner contact pattern 220, a contact band 230, a first contact pattern 241, a second contact pattern 242, a constant voltage electrode 30, and a heating member 40.

The base 21 may have a circular plate shape. The base 21 may include a dielectric material. For example, the base 21 may include aluminum nitride (AlN).

The outer dam 210 may be disposed by extending along the edge of base 21. The outer dam 210 may have a ring shape extending along the edge of the base 21 on a plane. The outer dam 210 may be protruded from the upper surface of the base 21. The outer dam 210 may guide the space where the substrate W is loaded on the base 21. In other words, the substrate W may be loaded between the outer dam 210. When the substrate W is loaded on the upper surface of the base 21, the substrate W may be spaced apart from the outer dam 210.

In some implementations, the base 21 may include an inner region CN including the center of base 21 and an outer region EG surrounding the inner region CN. The inner region CN and the outer region EG of base 21 may be regions divided into a plane area.

The inner region CN may have a circular shape centered on the center of the base 21 on a plane, and the outer region EG may extend along the direction of the circumference of base 21. In other words, the outer region EG may have a ring shape extending along the edge of the inner region CN. At this time, the radius of the inner region CN may be larger than the width according to the radial direction of the outer region EG. For example, the radius of inner region CN may be about 4/5 to about 14/15 of the width along the radial direction of base 21. As an example, the radius of the inner region CN may be about 120 mm to about 140 mm. The radius of the inner region CN may preferably be about 130 mm, but the radius of the inner region CN is not limited thereto.

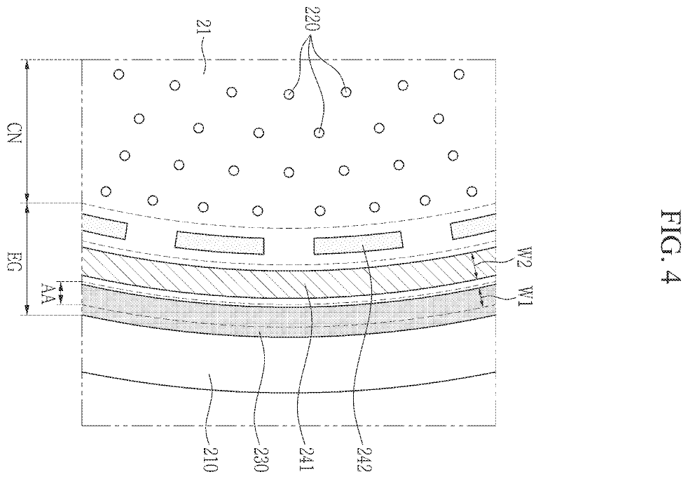

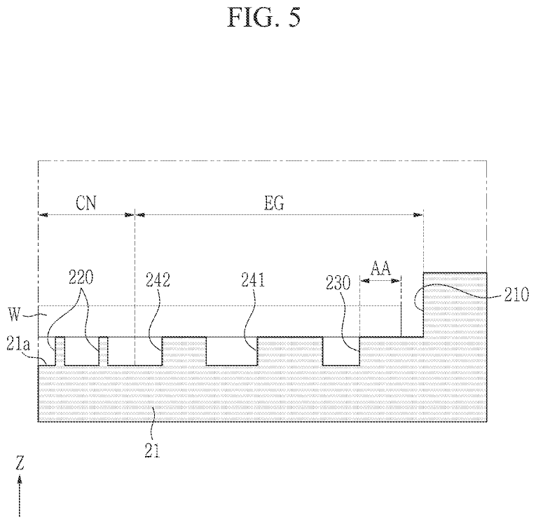

In some implementations, an inner contact pattern 220 may be disposed on the upper surface 21a of the base 21 in the inner region CN. Additionally, a contact band 230, a first contact pattern 241, and a second contact pattern 242 may be disposed on the upper surface 21a of the base 21 in the outer region EG. The inner region CN may mean a region where the inner contact pattern 220 is disposed. Additionally, the outer region EG may mean a region where the contact band 230, the first contact pattern 241, and the second contact pattern 242 are disposed. The inner contact pattern 220, the contact band 230, the first contact pattern 241, and the second contact pattern 242 are described later with reference to FIG. 4 and FIG. 5.

In some implementations, the substrate W may be loaded into some regions of the inner region CN and the outer region EG. Specifically, the substrate W completely overlap with the inner region CN in the third direction (the Z direction). For example, the substrate W may be loaded on the inner contact pattern 220 of the inner region CN. Additionally, the substrate W may overlap with some regions of the outer region EG in the third direction (the Z direction) and non-overlap with the remaining regions in the third direction (the Z direction). For example, the substrate W may be loaded on the first and second contact pattern 242 of the outer region EG and may be loaded on some regions of the contact band 230. That is, the substrate W may not be loaded in the remaining region of contact band 230.

Hereinafter, for better understanding and ease of description, the part of contact band 230 where the substrate W is loaded will be referred to as AA (hereinafter, ‘an overlapping region’). For example, in the overlapping region AA of the contact band 230, the substrate W may overlap the contact band 230 in the third direction (the Z direction).

The constant voltage electrode 30 may be embedded in base 21. The constant voltage electrode 30 may include a conductor, for example, metals such as tungsten (W), copper (Cu), nickel (Ni), molybdenum (Mo), nickel-chromium alloy (Ni—Cr alloy), nickel-aluminum alloy (Ni—Al alloy), etc., or conductive ceramics such as tungsten carbide (WC), molybdenum carbide (MoC), titanium nitride (TiN), etc. As an example, the constant voltage electrode 30 may be an adsorption electrode.

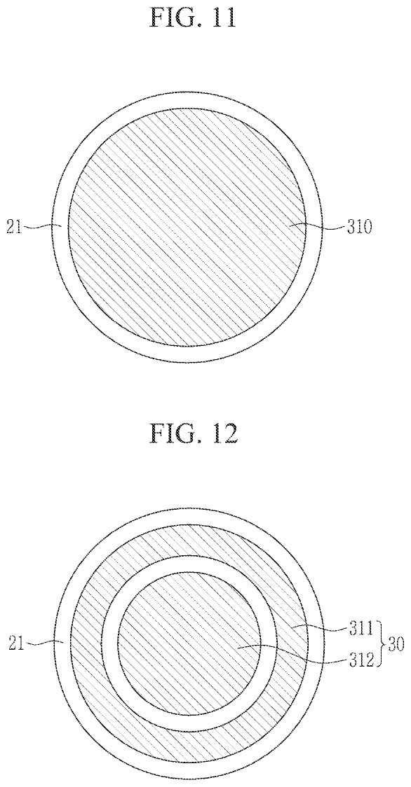

The constant voltage electrode 30 may be electrically connected to a voltage supplier, and an electrostatic force may be generated between the contact patterns 220, 230, 241, and 242 and the substrate W by the voltage (e.g., a DC voltage) applied from the voltage supplier. Accordingly, the substrate W may be chucked on the substrate supporter 20. As an example, the substrate W may be chucked to the contact patterns 220, 230, 241, and 242 by Coulomb force and Johnson-Rahbek effect. Here, Johnson-Rabek effect, when a voltage is applied to the constant voltage electrode 30, means that the surface of the contact patterns 220, 230, 241, and 242 is charged and polarized and then the electrostatic force acts between the substrate W and the contact patterns 220, 230, 241, and 242. The specific shape of the constant voltage electrode 30 will be described later with reference to FIG. 11 to FIG. 13.

The heating member 40 may be disposed inside the base 21 of the substrate supporter 20. The heating member 40 may be embedded in the base 21. The heating member 40 may be disposed under the constant voltage electrode 30, but is not limited thereto. The heating member 40 may heat the substrate W loaded on the substrate supporter 20 to a predetermined temperature.

The showerhead structure 50 may be disposed on the chamber 10 to penetrate the chamber 10. The showerhead structure 50 may be spaced apart from the substrate supporter 20 and disposed on the substrate supporter 20. That is, the showerhead structure 50 may be provided at the upper part of the chamber 10 to face the substrate supporter 20. The showerhead structure 50 may spray a process gas toward the substrate W within the chamber 10. The showerhead structure 50 may control a thickness distribution and a film quality characteristic of the deposited material by controlling the uniformity and distribution of the process gas sprayed on the substrate W within the chamber 10. Here, the process gas may be a gas used in the substrate processing process performed in the substrate processing apparatus 1.

The showerhead structure 50 may include a gas inflow port through which the process gas flows and a plurality of spray ports through which the inflowed process gas is discharged. In some implementations, the showerhead structure 50 may cover the upper part of the chamber 10 to provide a closed and sealed space where a process is performed together with the chamber 10, but the shape of the chamber 10 and the showerhead structure 50 is not limited thereto. Alternatively, the process chamber may provide the closed and sealed space, the gas inflow port may penetrate the process chamber, and the remaining portion of the showerhead structure may have a shape disposed inside the process chamber. In some implementations, the showerhead structure 50 may be connected to a power supply device and/or a ground electrode to generate plasma, but is not limited thereto.

The substrate processing apparatus 1 according to an implementation may further include a constant voltage supplier. The constant voltage supplier may supply a voltage to the constant voltage electrode 30. As an example, the constant voltage supplier may supply a DC voltage of a certain magnitude to the constant voltage electrode 30. Accordingly, the surface of the contact patterns 220, 230, 241, and 242 may be charged and polarized by the voltage applied to the constant voltage electrode 30, and an electrostatic force may be acted between the substrate W and the contact patterns 220, 230, 241, and 242.

Next, the substrate supporter according to an implementation is described with reference to FIG. 4 and FIG. 5.

FIG. 4 is an example enlarged top plan view of a region of FIG. 3. FIG. 5 is an enlarged cross-sectional view of a part of an example of a substrate supporter.

Referring to FIG. 4 and FIG. 5, as described above, a substrate supporter 20 may include a plurality of inner contact patterns 220, a contact band 230, a first contact pattern 241, and a second contact pattern 242.

The plurality of inner contact patterns 220 may be disposed within the inner region CN. For example, the plurality of inner contact pattern 220 may be disposed on the upper surface 21a of the base 21 of the inner region CN. The plurality of inner contact pattern 220 may be protruded from the upper surface 21a of the base 21. The plurality of inner contact pattern 220 may be arranged radially from the center of the base 21 with the same interval. The plurality of inner contact patterns 220 may each have a circular shape. However, it is not limited thereto, the plurality of inner contact pattern 220 each may have various shapes such as ellipse, polygon, etc. The plurality of inner contact patterns 220 may include the same material as the base 21. For example, the plurality of inner contact pattern 220 may include aluminum nitride (AlN). The inner contact pattern 220 may be integrated by being in contact with the base 21 without a boundary surface, but is not limited thereto.

The contact band 230, the first contact pattern 241, and the second contact pattern 242 may be disposed within the outer region EG. The contact band 230, the first contact pattern 241, and the second contact pattern 242 may be disposed sequentially from the side surface of the outer dam 210 in the outer region EG toward the center of base 21.

The contact band 230 may be disposed along the edge of the outer region EG of the base 21. The contact band 230 may extend along the circumferential direction of the base 21. The contact band 230 may have a ring shape extending along the circumferential direction of the base 21. The contact band 230 may be disposed on the inside of the outer dam 210. The contact band 230 may be connected to the outer dam 210. As an example, the contact band 230 may be disposed in a region within about 145 mm to about 150 mm in the radial direction from the center of base 21, but is not limited thereto. For example, the contact band 230 may be disposed in a region within about 148 mm to about 150 mm in the radial direction from the center of the base 21.

The contact band 230 may be protruded from the upper surface 21a of the base 21. For example, the height at which the contact band 230 is protruded from the upper surface 21a of the base 21 may be substantially equivalent to the height at which the inner contact pattern 220 is protruded from the upper surface 21a of the base 21. The height at which the contact band 230 is protruded from the upper surface 21a of the base 21 may be smaller than the height at which the outer dam 210 is protruded from the upper surface 21a of the base 21. However, it is not limited to this, and the height at which the second contact pattern 242 is protruded from the upper surface 21a of the base 21 may be substantially equivalent to the height at which the outer dam 210 is protruded from the upper surface 21a of the base 21.

In some implementations, the substrate W may be provided in some regions of the contact band 230. For example, the substrate W may be provided on the overlapping region AA to be spaced apart from the outer dam 210. The contact band 230 may chuck the substrate W in the overlapping region AA. That is, when the substrate W is chucked to the substrate supporter 20, the upper surface of the overlapping region AA of the contact band 230 may be in contact with the lower surface of the substrate W. At this time, the remaining region of the contact band 230 may not be in contact with the substrate W. The contact band 230 may include the same material as the base 21. For example, the contact band 230 may include aluminum nitride (AlN), but is not limited thereto. The contact band 230 may be integrated by being in contact with the base 21 without a boundary surface, but is not limited thereto.

The first contact pattern 241 may be disposed inside the contact band 230 in the outer region EG. The first contact pattern 241 may be a contact pattern closest to the contact band 230 into the inside of the contact band 230. That is, the contact band 230 may be disposed between the first contact pattern 241 and the outer dam 210. The first contact pattern 241 may be disposed away from the contact band 230. As an example, the first contact pattern 241 may be disposed in a region within about 140 mm to about 145 mm in the radial direction from the center of base 21, but is not limited thereto. For example, the first contact pattern 241 may be disposed in a region within about 146 mm to about 148 mm in the radial direction from the center of base 21.

The first contact pattern 241 may be protruded from the upper surface 21a of the base 21. For example, the height at which the first contact pattern 241 is protruded from the upper surface 21a of the base 21 may be smaller than the height at which the outer dam 210 is protruded from the upper surface 21a of the base 21. However, it is not limited to this, and the height of the first contact pattern 241 and the height of the outer dam 210 may be changed in various ways. For example, the height at which the first contact pattern 241 is protruded from the upper surface 21a of the base 21 may be substantially equivalent to the height at which the contact band 230 is protruded from the upper surface 21a of the base 21.

The first contact pattern 241 may extend along the circumferential direction of the base 21. For example, the first contact pattern 241 may have a ring shape extending along the circumferential direction of the base 21. The substrate W may be provided on the first contact pattern 241, and the first contact pattern 241 may chuck the substrate W. That is, when the substrate W is chucked to the substrate supporter 20, the upper surface of the first contact pattern 241 may be in contact with the lower surface of the substrate W.

In some implementations, a contact ratio C/R of the first contact pattern 241 may be greater than the contact ratio C/R of the contact band 230. Here, the contact ratio C/R may refer to a ratio of the area where the contact pattern is in contact with the substrate W to the entire area of the substrate W. That is, in some implementations, the contact ratio C/R of the first contact pattern 241 may mean the ratio of the area where the first contact pattern 241 is in contact with the substrate W to the entire area of the substrate W. Additionally, the contact ratio C/R of the contact band 230 may mean the ratio of the area where the contact band 230 is in contact with the substrate W to the entire area of the substrate W.

Specifically, in order for the process (e.g., the deposition process or the etching process) to proceed uniformly on the upper surface of the substrate W, the contact band 230, the first contact pattern 241, the second contact pattern 242, and the inner contact pattern 220 need to chuck the substrate W with the uniform electrostatic force. Meanwhile, a warpage may occur in the substrate W loaded into the substrate processing apparatus 1. For example, when a heat treatment process is performed on the substrate W in the preceding process, the edge of the substrate W may be deformed and bent due to a thermal expansion. Accordingly, when the substrate W is loaded on the substrate supporter 20, a problem may occur in which the edge of the substrate W does not completely contact the substrate supporter 20. Particularly, when the substrate W is in contacts with the contact band 230 due to the electrostatic force of the contact band 230, a problem may occur in which the first contact pattern 241 cannot chuck the substrate W. Additionally, the substrate supporter 20 generates the excessive electrostatic force on the contact band 230 to chuck the substrate W, which may cause a damage to the lower surface of the substrate W.

In the substrate processing apparatus 1 according to an implementation, as the contact ratio C/R of the first contact pattern 241 is larger than the contact ratio C/R of the contact band 230, even when the substrate W with the warpage is loaded, the contact band 230 and the first contact pattern 241 may chuck the substrate W with the uniform electrostatic force. In addition, as the first contact pattern 241 chucks the substrate W with the uniform electrostatic force with the contact band 230, it is possible to prevent the lower surface of the substrate W from being damaged due to the excessive electrostatic force acting on the edge of the substrate W.

Therefore, the area of the first contact pattern 241 may be larger than the area of the overlapping region AA where the contact band 230 overlaps with the substrate W in the third direction (the Z direction). Accordingly, the contact ratio of the first contact pattern 241 may be greater than the contact ratio of the substrate W to the contact band 230. Here, the area of the first contact pattern 241 may be the area of the upper surface of the first contact pattern 241 on a plane. Additionally, the area of the overlapping region AA of the contact band 230 may be the area of the upper surface of the contact band 230 in the overlapping region AA on a plane.

Additionally, the second width W2 along the radial direction of the base 21 of the first contact pattern 241 may be larger than the first width W1 along the radial direction of the base 21 of the overlapping region AA of the contact band 230. Accordingly, the contact ratio of the first contact pattern 241 may be greater than the contact ratio of the contact band 230.

The first contact pattern 241 may include the same material as at least one of the base 21, the inner contact pattern 220, and the contact band 230. For example, the first contact pattern 241 may include aluminum nitride (AlN), but is not limited thereto.

The second contact pattern 242 may be disposed inside the first contact pattern 241. The second contact pattern 242 may be a contact pattern closest to the first contact pattern 241 inside the first contact pattern 241. That is, the first contact pattern 241 may be disposed between the second contact pattern 242 and the contact band 230, and the second contact pattern 242 may be disposed between the inner contact pattern 220 and the first contact pattern 241. The second contact pattern 242 may be disposed away from the inner contact pattern 220 and may first contact pattern 241. As an example, the second contact pattern 242 may be disposed in a region within about 130 mm to about 140 mm in the radial direction from the center of base 21, but is not limited thereto. For example, the first contact pattern 241 may be disposed in a region within about 130 mm to about 146 mm in the radial direction from the center of base 21.

The second contact pattern 242 may be protruded from the upper surface 21a of the base 21. For example, the height at which the second contact pattern 242 is protruded from the upper surface 21a of the base 21 may be substantially equivalent to the height at which the first contact pattern 241 is protruded from the upper surface 21a of the base 21. The height at which the second contact pattern 242 is protruded from the upper surface 21a of the base 21 may be smaller than the height at which the outer dam 210 is protruded from the upper surface 21a of the base 21. However, it is not limited to this, and the height at which the second contact pattern 242 is protruded from the upper surface 21a of the base 21 may be substantially equivalent to the height at which the outer dam 210 is protruded from the upper surface 21a of the base 21.

The second contact pattern 242 may include a plurality of second sub-contact patterns 242P. The plurality of second sub-contact patterns 242P may be extended along the circumferential direction of the base 21. The plurality of second sub-contact patterns 242P may be respectively arranged radially from the center of base 21 with the equal interval. In other words, each of the plurality of second sub-contact patterns 242P may be arranged to be spaced apart along the direction of the circumference of base 21. The substrate W may be provided on the plurality of second sub-contact patterns 242P, and the plurality of second sub-contact patterns 242P may chuck the substrate W. In other words, when the substrate W is chucked to the substrate supporter 20, the upper surface of the plurality of second sub-contact patterns 242P may be in contact with the lower surface of the substrate W.

In some implementations, the contact ratio C/R of the second contact pattern 242 may be smaller than the contact ratio C/R of the contact band 230. For example, the contact ratio C/R of the second contact pattern 242 may be 30% or more and less than 100% of the contact ratio C/R of the contact band 230. This, when the contact band 230 and the first contact pattern 241 chuck the substrate W with the uniform electrostatic force, may be a ratio for the second contact pattern 242 to chuck the substrate W with the electrostatic force of a uniform magnitude along with the contact band 230 and the first contact pattern 241. Here, the contact ratio C/R of the second contact pattern 242 may mean the ratio of the area where the second contact pattern 242 is in contact with the substrate W to the entire area of the substrate W. Additionally, the contact ratio C/R of the contact band 230 may mean the ratio of the area where the contact band 230 is in contact with the substrate W to the entire area of the substrate W.

In other words, the area of the second contact pattern 242 may be 30% to 100% of the area of the overlapping region AA where the contact band 230 overlaps with the substrate W in the third direction (the Z direction). Additionally, the third width W3 along the radial direction of base 21 of the second contact pattern 242 may be smaller than the first width W1 along the radial direction of base 21 of the overlapping region AA. Here, the area of the second contact pattern 242 may mean the sum of the areas of the upper surface of the plurality of second sub-contact patterns 242P on a plane.

The second contact pattern 242 may include the same material as at least one of the base 21, the inner contact pattern 220, the contact band 230, and the first contact pattern 241. For example, the second contact pattern 242 may include aluminum nitride (AlN), but is not limited thereto.

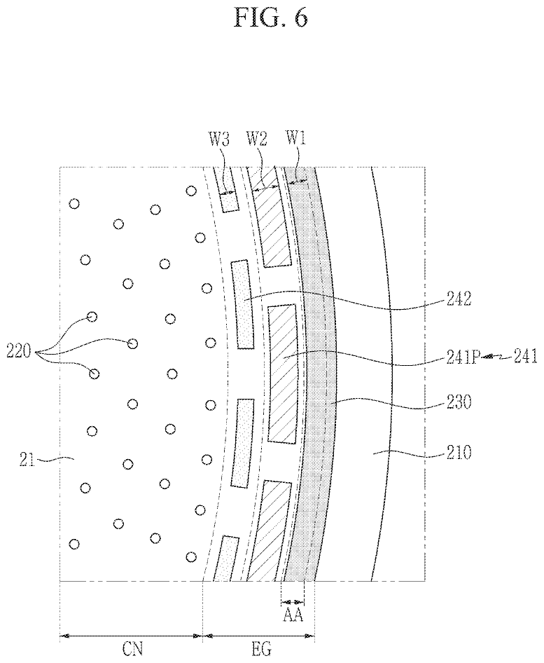

In FIG. 4 and FIG. 5, it is explained that the first contact pattern 241 of the substrate supporter 20 according to an implementation has the ring shape, and the second contact patterns 242 are arranged to be spaced apart along the circumferential direction of the base 21, but is not limited thereto. This is described later with reference to FIG. 6 to FIG. 10.

In the substrate processing apparatus 1 according to some implementations, as since the contact ratio C/R of the first contact pattern 241 is larger than the contact ratio C/R of the contact band 230, even when the substrate W with warpage is loaded, the contact band 230 and the first contact pattern 241 may chuck the substrate W with the uniform electrostatic force. Accordingly, it is possible to prevent the damage to the lower surface of the substrate W due to the excessive electrostatic force acting on the edge of the substrate W, and the reliability of the substrate processing apparatus may be improved.

Next, variations of the first and second contact patterns 242 are described with reference to FIG. 6 to FIG. 10.

FIG. 6 to FIG. 10 are example top plan views corresponding to a region of FIG. 3.

Referring to FIG. 6, the first contact pattern 241 may include a plurality of first sub-contact patterns 241P.

The plurality of first sub-contact patterns 241P may be extended along the circumferential direction of the base 21. The plurality of first sub-contact patterns 241P may be respectively arranged radially from the center of the base 21 with the equal interval. In other words, the plurality of first sub-contact patterns 241P may be arranged to be respectively spaced apart along the direction of the circumference of the base 21. The substrate W may be provided on the plurality of first sub-contact patterns 241P, and the plurality of first sub-contact patterns 241P may chuck the substrate W. In other words, when the substrate W is chucked to the substrate supporter 20, the upper surface of plurality of first sub-contact patterns 241P may be in contact with the lower surface of the substrate W.

In some implementations, the contact ratio C/R of the plurality of first sub-contact patterns 241P may be greater than the contact ratio of the contact band 230. In other words, the sum of the areas of the plurality of first sub-contact patterns 241P may be larger than the area of the overlapping region AA where the contact band 230 overlaps with the substrate W in the third direction (the Z direction). Additionally, the second width W2 according to the radial direction of the base 21 of the plurality of first sub-contact patterns 241P may be larger than the first width W1 according to the radial direction of the base 21 of overlapping region AA of the contact band 230. Here, the area of the plurality of first sub-contact patterns 241P may be the area of the upper surface of the plurality of first sub-contact patterns 241P.

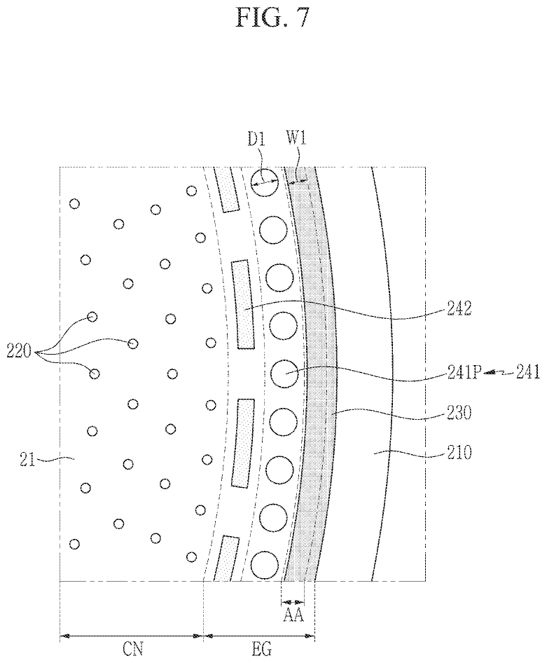

Referring to FIG. 7, the plurality of first sub-contact patterns 241P may be respectively arranged radially from the center of the base 21 with the equal interval. In other words, each of the plurality of first sub-contact patterns 241P may be arranged to be spaced apart along the direction of the circumference of base 21.

The plurality of first sub-contact patterns 241P may have a circular shape on a plane, respectively. At this time, the first diameter D1 of each of the plurality of first sub-contact patterns 241P may be larger than the first width W1 according to the radial direction of base 21 of the overlapping region AA.

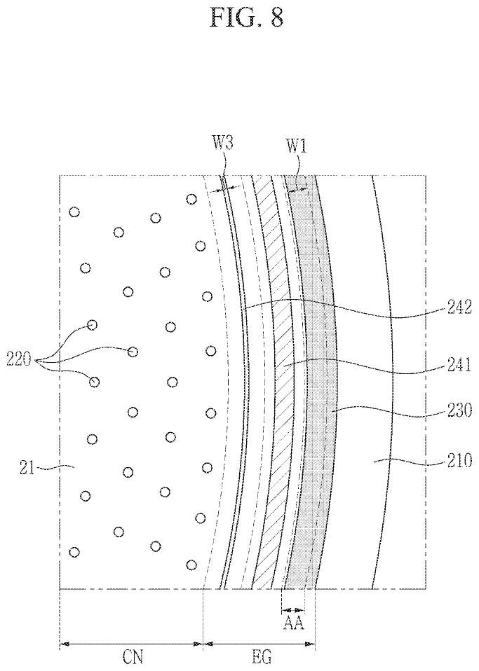

Referring to FIG. 8, the second contact pattern 242 according to an implementation may extend along the circumferential direction of the base 21. The second contact pattern 242 may have a ring shape extending along the circumferential direction of the base 21. Even in this case, the contact ratio C/R of the second contact pattern 242 may be smaller than the contact ratio C/R of the contact band 230. For example, the contact ratio C/R of the second contact pattern 242 may be 30% or more and less than 100% of the contact ratio of the contact band 230.

In other words, the area of second contact pattern 242 may be more than 30% and less than 100% of the area of overlapping region AA. Additionally, the third width W3 along the radial direction of the base 21 of the second contact pattern 242 may be smaller than the first width W1 along the radial direction of the base 21 of the overlapping region AA. For example, the third width W3 along the radial direction of the base 21 of the second contact pattern 242 may be more than 30% and less than 100% of the first width W1 along the radial direction of the base 21 of the overlapping region AA. Here, the area of the second contact pattern 242 may mean the sum of the areas of the upper surfaces of the plurality of second sub-contact patterns 242P on a plane.

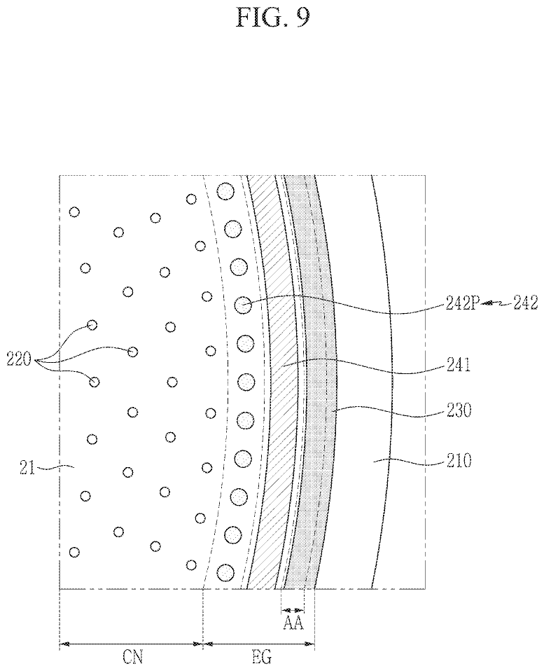

Referring to FIG. 9, the second contact pattern 242 may include a plurality of second sub-contact patterns 242P. The plurality of second sub-contact patterns 242P may be respectively arranged radially from the center of base 21 with the same interval. In other words, each of the plurality of second sub-contact patterns 242P may be arranged to be spaced apart along the direction of the circumference of base 21.

In some implementations, each of the plurality of second sub-contact patterns 242P may have a circular shape on a plane.

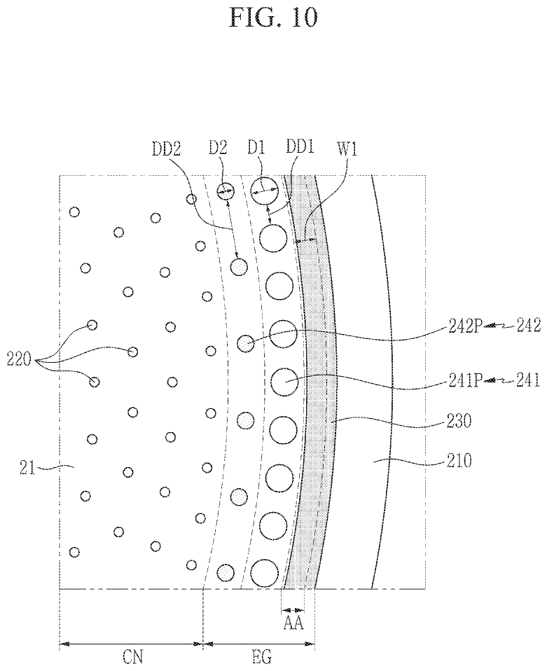

Referring to FIG. 10, the first contact pattern 241 may include a plurality of first sub-contact patterns 241P having a circle shape, and the second contact pattern 242 may include a plurality of second sub-contact patterns 242P having a circle shape.

In some implementations, the first diameter D1 of the plurality of first sub-contact patterns 241P may be larger than the second diameter D2 of the plurality of second sub-contact patterns 242P. This is the reason that the first diameter D1 of the plurality of first sub-contact patterns 241P is larger than the first width W1 along the radial direction of the base 21 of the overlapping region AA, and the second diameter D2 of the plurality of second sub-contact patterns 242P is smaller than the first width W1 along the radial direction of the base 21 of the overlapping region AA.

Additionally, the first interval DD1 between the plurality of first sub-contact patterns 241P may be smaller than the second interval DD2 between the plurality of second sub-contact patterns 242P. Accordingly, the sum of the areas of the plurality of first sub-contact patterns 241P may be larger than the sum of the areas of the plurality of second sub-contact patterns 242P.

Next, numerous variations of the constant voltage electrode 30 will be described with reference to FIG. 11 to FIG. 13.

FIG. 11 to FIG. 13 are top plan views showing an example of a constant voltage electrode of a substrate processing apparatus.

Referring to FIG. 11, the constant voltage electrode 30 may be a bipolar type or a monopolar type. As an example, as shown in FIG. 10, the constant voltage electrode 30 may have a monopolar type consisting of one circular electrode 310. The electrostatic force may be generated by applying a DC voltage to the constant voltage electrode 30.

As another example, as shown in FIG. 11, the constant voltage electrode 30 may have a bipolar type including a circular inner electrode 312 and a ring-shaped outer electrode 311. A positive voltage may be applied to one of the internal electrode 312 and the external electrode 311, and a negative voltage may be applied to the other electrode.

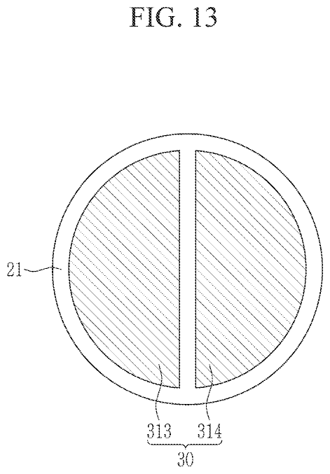

As another example, as shown in FIG. 13, the constant voltage electrode 30 may have a bipolar type in which a first semicircular electrode 313 and a second semicircular electrode 314 are disposed symmetrically left and right. A positive voltage may be applied to one of the first semicircular electrode 313 and the second semicircular electrode 314, and a negative voltage may be applied to the other.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While this disclosure has been described in connection with implementations, it is to be understood that the disclosure is not limited to the disclosed implementations. On the contrary, it is intended to cover various modifications and equivalent arrangements included within the spirit and scope of the appended claims.

What is claimed is:

1. A substrate supporter including an upper surface on which a substrate is loaded, comprising:
a base;
an outer dam extending along an edge of the base;
a contact band connected with the outer dam, the contact band extending along a circumferential direction of the base, wherein the substrate is loaded onto the contact band; and
a first contact pattern disposed adjacent to the contact band and extending into an inside of the contact band, the first contact pattern extending along the circumferential direction of the base,
wherein an area of the first contact pattern is larger than an area where the contact band overlaps with the substrate.

2. The substrate supporter of claim 1, wherein:
the contact band includes an overlapping region that overlaps the substrate,
the overlapping region and the first contact pattern both have a ring shape, and
a width of the first contact pattern along a radial direction of the base is greater than a width of the overlapping region along the radial direction of the base.

3. The substrate supporter of claim 1, wherein:
the first contact pattern includes a plurality of first sub-contact patterns that are spaced apart along the circumferential direction of the base.

4. The substrate supporter of claim 3, wherein:
each first sub-contact pattern of the plurality of first sub-contact patterns has a circular shape on a plane.

5. The substrate supporter of claim 1, wherein:
a height at which the contact band protrudes from an upper surface of the base is a same as a height at which the first contact pattern protrudes from the upper surface of the base.

6. The substrate supporter of claim 1, wherein:
the base includes an inner region and an outer region surrounding the inner region,
the contact band and the first contact pattern are disposed in the outer region, and
a radius of the inner region is 4/5 to 14/15 of a radius of the base.

7. The substrate supporter of claim 1, comprising:
a second contact pattern disposed adjacent to the first contact pattern and extending into an inside of the first contact pattern, the second contact pattern extending along the circumferential direction of the base, and
an area of the second contact pattern is more than 30% and less than 100% of the area where the contact band overlaps with the substrate.

8. The substrate supporter of claim 7, wherein:
at least one contact pattern of the first contact pattern or the second contact pattern has a ring shape.

9. The substrate supporter of claim 7, wherein:
the second contact pattern includes a plurality of second sub-contact patterns that are spaced apart along the circumferential direction of the base.

10. The substrate supporter of claim 9, wherein:
the first contact pattern includes a plurality of first sub-contact patterns that are spaced apart along the circumferential direction of the base,
the plurality of first sub-contact patterns and the plurality of second sub-contact patterns have circle shapes, respectively, and
a diameter of the plurality of second sub-contact patterns is smaller than a diameter of the plurality of first sub-contact patterns.

11. The substrate supporter of claim 10, wherein:
a distance between the plurality of first sub-contact patterns is smaller than a distance between the plurality of second sub-contact patterns.

12. The substrate supporter of claim 1, wherein:
the contact band and the first contact pattern include aluminum nitride.

13. A substrate supporter including an upper surface on which a substrate is loaded, comprising:
a base including an inner region and an outer region surrounding the inner region;
an outer dam extending along an edge of the base;
a plurality of inner contact patterns equally spaced apart in the inner region;
a contact band connected with the outer dam and extending along a circumferential direction of the base, the contact band disposed in the outer region, and the substrate being loaded onto the contact band; and
a first contact pattern disposed adjacent to the contact band and extending into an inside of the contact band, the first contact pattern extending along the circumferential direction of the base, the first contact pattern disposed in the outer region, and
an area of the first contact pattern is larger than an area where the contact band overlaps with the substrate.

14. The substrate supporter of claim 13, comprising:
a second contact pattern disposed on an inner side of the first contact pattern, the second contact pattern disposed in the outer region and extending along the circumferential direction of the base.

15. The substrate supporter of claim 14, wherein:
an area of the second contact pattern is more than 30% and less than 100% of the area where the contact band overlaps with the substrate.

16. The substrate supporter of claim 14, wherein:
at least one contact pattern of the first contact pattern or the second contact pattern has a ring shape on a plane.

17. The substrate supporter of claim 13, wherein:
the substrate supporter includes a constant voltage electrode, the constant voltage electrode embedded in the base and configured to generate an electrostatic force between the substrate supporter and the substrate.

18. A substrate supporter including an upper surface on which a substrate is loaded, comprising:
a base;
an outer dam extending along an edge of the base;
a contact band connected with the outer dam, the contact band extending along a circumferential direction of the base, wherein the substrate is loaded onto the contact band;
a first contact pattern disposed adjacent to an inside of the contact band and extending along the circumferential direction of the base; and
a second contact pattern disposed adjacent to an inside of the first contact pattern and extending along the circumferential direction of the base,
wherein the first contact pattern is disposed between the outer dam and the second contact pattern, and
a ratio of an area where the first contact pattern is in contact with the substrate to an entire area of the substrate is greater than a ratio of an area where the contact band is in contact with the substrate to the entire area of the substrate.

19. The substrate supporter of claim 18, wherein:
an area where the second contact pattern is in contact with the substrate is more than 30% and less than 100% of an area where the contact band overlaps with the substrate.

20. The substrate supporter of claim 19, wherein:
at least one contact pattern of the first contact pattern or the second contact pattern has a ring shape on a plane.
